(19) United States
(12) Patent Application Publication
(10) Pub. No.: US 2023/0113274 A1
(43) Pub. Date: Apr. 13, 2023

(54) SUBSTRATE AND SEMICONDUCTOR LASER

(71) Applicant: ams-OSRAM International GmbH, Regensburg (DE)

(72) Inventors: Daniel Dietze, Regensburg (DE); Dirk Becker, Langquaid (DE)

(73) Assignee: ams-OSRAM International GmbH, Regensburg (DE)

(21) Appl. No.: 17/801,987

(22) PCT Filed: Feb. 23, 2021
(86) PCT No.: PCT/EP2021/054406

§ 371 Date: Aug. 24, 2022

(30) Foreign Application Priority Data
Feb. 26, 2020 (DE) 102020105005.4

(51) Int. Cl. H01S 5/0239; H01S 5/02; H01S 5/02345; H05K 1/02; H05K 1/03; H05K 1/11; H05K 1/18

(52) U.S. Cl. CPC H01S 5/0239; H01S 5/0206; H01S 5/02345; H05K 1/0298; H05K 1/0306; H05K 1/113; H05K 1/181; H05K 2201/10121; H05K 2201/10015; H05K 2201/0191; H05K 2201/096

(57) ABSTRACT

In one embodiment, the substrate is configured for a semiconductor laser diode and comprises a plurality of substrate layers. The substrate layers include insulating layers and carrier layers, which are thicker. A plurality of electrical contact surfaces, which are configured for the semiconductor laser diode, a laser capacitor and a control chip, are located on an assembling side of a first, uppermost substrate layer, which is an insulating layer. Electrical conductor tracks, which electrically interconnect the contact surfaces, are located on the one hand between the first insulating layer and a second insulating layer, and on the other hand between the second insulating layer and a third substrate layer, which is preferably an insulating layer.

### CROSS-REFERENCE TO RELATED APPLICATIONS

This patent application is a national stage entry from International Application No. PCT/EP2021/054406, filed on Feb. 23, 2021, published as International Publication No. WO 2021/170562 A1 on Sep. 2, 2021, and claims priority under 35 U.S.C. § 119 from German patent application 10 2020 105 005.4, filed Feb. 26, 2020, the entire contents of all of which are incorporated by reference herein.

### FIELD

A substrate for a semiconductor laser is provided.

Furthermore, a semiconductor laser is provided.

### BACKGROUND

Document US 2019/0312407 A1 refers to an arrangement with an electrical component.

An object to be solved is to provide a substrate for a semiconductor laser that allows small rise times for a laser emission.

This object is achieved, inter alia, by a substrate and by a semiconductor laser having the features of the independent patent claims. Preferred further embodiments are the subject of the dependent claims.

### SUMMARY

According to at least one embodiment, the substrate is configured for a semiconductor laser diode. For example, only a single semiconductor laser diode is provided on the substrate. Alternatively, the substrate is configured for a plurality of semiconductor laser diodes. If a plurality of semiconductor laser diodes are present, they may be identical in construction and, in particular, may be set up to emit radiation of the same wavelength, or different semiconductor laser diodes may be present, for example, to emit laser radiation at different wavelengths.

According to at least one embodiment, the substrate comprises a plurality of substrate layers. The substrate layers are preferably planar or approximately planar. Between the substrate layers there are preferably electrically conductive layers, in particular metallizations. At least some of the conductive layers are structured so that dedicated electrically conductive surfaces and electrically conductive areas result between the substrate layers. The substrate layers themselves are preferably electrically insulating.

According to at least one embodiment, the substrate layers comprise multiple insulating layers. The insulating layers are comparatively thin.

According to at least one embodiment, the substrate layers further comprise a plurality of carrier layers. The carrier layers are each thicker than the insulating layers.

Within the manufacturing tolerances, all carrier layers are preferably of the same thickness. The same preferably applies to the insulating layers. It is also possible for the substrate to have only substrate layers that are either insulating layers or carrier layers.

According to at least one embodiment, a plurality of electrical contact surfaces are provided on a first, uppermost insulating layer. These electrical contact surfaces are preferably provided for a semiconductor laser diode, for a laser capacitor and for a control chip. The first, uppermost insulating layer thus forms an assembling side of the substrate, the assembling side being set up for assembly with the aforementioned electrical components and optionally with further electrical components.

The substrate layers are numbered consecutively starting from the assembling side. This means that the first substrate layer, which corresponds to the first insulating layer, is located directly at the assembling side and forms the assembling side. A second, third, fourth substrate layer and so on are located further away from the assembling side according to their respective numbering. It is possible that, viewed from above the assembling side, the substrate layers are arranged congruently or substantially congruently, at least with regard to outer contours of the substrate layers.

The numbering preferably extends continuously and uninterruptedly across the insulating layers and the carrier layers. This means that if the last insulating layer is the n-th substrate layer, then the first of the carrier layers is designated as the n+1-th carrier layer. n is a natural number here.

According to at least one embodiment, the contact surfaces for the semiconductor laser diode, the laser capacitor and the control chip are electrically interconnected via electrical conductor tracks. In addition to the electrical conductor tracks, there are preferably also electrical through-holes which run between individual substrate layers or between several substrate layers and connect the electrical conductor tracks to one another in different planes defined by the substrate layers. The conductor tracks preferably run parallel to the assembling side and the through-holes preferably run perpendicular to the assembling side.

According to at least one embodiment, electrical conductor tracks are provided for interconnecting the contact surfaces for the semiconductor laser diode, for the laser capacitor and for the control chip, which are located on the one hand between the first insulating layer and the second insulating layer and on the other hand between the second insulating layer and the third insulating layer. In other words, the electrical conductor tracks connecting the aforementioned contact surfaces may be limited to the uppermost three substrate layers. If only two insulating layers are present, the third insulating layer is replaced by a topmost one of the carrier layers.

In at least one embodiment, the substrate is adapted for a semiconductor laser diode and comprises a plurality of substrate layers. The substrate layers include a plurality of insulating layers and a plurality of carrier layers, wherein the carrier layers are thicker than the insulating layers. A plurality of electrical contact surfaces arranged for the semiconductor laser diode, for a laser capacitor, and for a control chip are located on an assembling side of a first uppermost substrate layer that is an insulating layer, wherein the substrate layers are sequentially numbered starting with the first insulating layer in a direction away from the assembling side. Electrical conductor tracks, which electrically interconnect the contact surfaces for the semiconductor laser diode, the laser capacitor and the control chip, are located on the one hand between the first insulating layer and a second substrate layer, which is also an insulating layer, and on the other hand between the second substrate layer and a third substrate layer, which is again preferably an insulating layer, alternatively a carrier layer.

This substrate can be used to build a high-frequency optimized semiconductor laser.

Thus, the substrate is used in particular for a fast-switching semiconductor laser that includes a driver circuit, also referred to as a driver IC or control chip, and any other components on the substrate.

A parasitic inductance of a conductor loop between the driver and the laser diode conventionally limits an achievable slew rate and/or rise time of a laser current for the laser diode and limits a maximum slope of a laser pulse.

Furthermore, such drivers conventionally have a preamplifier stage that converts a differential trigger signal, for example, LVDS, into an absolute control signal for a laser switch. In this process, high switching currents flow in a very short time, which can cause a voltage dip on a supply pin of the substrate due to the parasitic inductance of the substrate. These voltage dips can propagate as spurious signals back into a circuit board on which the semiconductor laser is mounted. Such spurious signals can lead to problems with respect to an electromagnetic compatibility and are possibly associated with radio frequency emission.

Such parasitic inductances are usually proportional to the area of the associated conductor loop. With the approach described herein, the area of the conductor loop can be minimized. Rewiring usually requires multiple planes of electrical traces in the substrate, with a forward path and a reverse path for the relevant currents preferably implemented in adjacent, contiguous electrical planes. Thus, a reduction of the parasitic inductance is enabled by the small thicknesses of the insulating layers. Mechanical stability of the substrate is ensured by the carrier layers.

Thus, a layer stack is not symmetrically constructed in the substrate described herein, which is designed as a multilayer substrate. The uppermost layers are kept as thin as possible to minimize a distance between the forward conductor and the return conductor in the current path. If the distance between the forward conductor and the return conductor is too large, a direct return path of the current in question would no longer be possible and the associated inductances would increase considerably. Achievable switching times of the semiconductor laser diode would increase to the same extent.

In the substrate described herein, tracks from a current source, in particular from a buffer capacitor, to the semiconductor laser diode, in particular a VCSEL, are designed to be as symmetrical as possible to allow symmetrical power injection. The internal current paths are laid and designed so that the forward conductors and the return conductors overlap and so that the return path of the current is kept as short as possible. Interruptions in the return paths are minimized.

A power string is also preferably passed through a center of the substrate and surrounded by grounded, electrically conductive surfaces between the substrate layers. This minimizes the emission of high-frequency signals.

In addition, a current-carrying part of the semiconductor laser is preferably not led to the outside to guarantee low high-frequency emission.

Thus, shorter switching times and better high-frequency shielding can be achieved with the substrate described here.

According to at least one embodiment, all substrate layers are made of the same material. Alternatively or additionally, all substrate layers are made of a ceramic. In particular, the substrate layers are each made of aluminum oxide.

According to at least one embodiment, a thickness of the insulating layers is at least 40 μm or 70 μm each. Alternatively or additionally, the thickness of the insulating layers is at most 0.3 mm or 0.2 mm. For example, the insulating layers have a thickness of about 100 μm.

According to at least one embodiment, a thickness of the carrier layers is at least 0.2 mm or 0.3 mm each. Alternatively or additionally, the carrier layers have a thickness of at most 1 mm or 0.8 mm or 0.6 mm or 0.4 mm. In particular, the thickness of the carrier layers is about 350 μm.

According to at least one embodiment, the carrier layers are thicker than the insulating layers by at least a factor of 1.5 or 2 or 3. Alternatively or additionally, this factor is at most 10 or 7 or 5. Thus, the insulating layers can be very thin for shorter switching times of the semiconductor laser diode, whereas sufficient mechanical stabilization of the substrate is provided by the thicker carrier layers.

According to at least one embodiment, the substrate has a mounting side. Electrical connection areas for external electrical contacting of the substrate are located on the mounting side. The mounting side is thus an outer side of a last one of the substrate layers, which is in particular a last one of the carrier layers. The last carrier layer is thus preferably the substrate layer which is furthest away from the assembling side.

According to at least one embodiment, one or more electrical connection surfaces are provided for a supply voltage for the semiconductor laser diode. An electrical through-hole leads from this electrical connection surface at least up to the second insulating layer or also up to the first insulating layer. In particular, this through-hole or these through-holes are led directly from the associated connection surface to the second insulating layer or to the first insulating layer, so that these through-holes do not need to have any steps, kinks or bumps.

According to at least one embodiment, the electrical through-hole for the connection surface for the supply voltage of the semiconductor laser diode is located in a central region of the substrate. The central region is surrounded by an edge region.

For example, the central area occupies the innermost 70% or 80% of an area of the substrate, as seen in plan view of the assembling side. The edge area can have a uniform width so that the edge area can surround the central area as a uniformly wide frame in a closed path. The subdivision into the central area and the edge area can be fictitious, so that this subdivision does not need to be connected to any physical features on the substrate, such as a parting line on the assembling side.

According to at least one embodiment, the at least one through-hole for the connection surface for the supply voltage, which extends to the second or to the first insulating layer, is surrounded by at least one shielding conductor track between each of the carrier layers. The shielding conductor tracks are preferably connected to at least one electrical connection surface on the asssembling side for an earth connection. In other words, the shielding conductor tracks between the substrate layers act similarly to a shield in a coaxial cable. This allows high-frequency emissions from the through-hole to be reduced.

According to at least one embodiment, at least three or at least four through-holes and/or at most 16 or at most eight through-holes are present for the connection surface for the supply voltage of the semiconductor laser diode. This means that there is a comparatively small number of through-holes for this supply voltage.

According to at least one embodiment, the at least one through-hole for the supply voltage of the semiconductor laser diode is located below a connection surface for the control chip, as seen in a top view of the assembling side. That is, when the control chip is mounted on the substrate, the control chip covers the at least one corresponding through-hole. Viewed from above, this at least one through-hole is thus preferably placed next to the semiconductor laser diode and also next to the laser capacitor.

According to at least one embodiment, the substrate comprises electrical contact surfaces on the assembling side for a further capacitor. The further capacitor serves in particular as a buffer capacitor for a switching element with which the semiconductor laser diode is switched on.

According to at least one embodiment, electrical conductor tracks which electrically interconnect the contact surfaces for the further capacitor and for the control chip are located on the one hand between the first insulating layer and the second insulating layer and on the other hand between the second insulating layer and the third substrate layer, which is preferably an insulating layer. It is possible that the conductor tracks for the electrical interconnection of these contact surfaces are limited to the area between the first and the second insulating layer and between the second and the third substrate layer.

According to at least one embodiment, the conductor tracks that electrically interconnect the contact surfaces for the further capacitor and for the control chip run partially or completely on top of each other as viewed from above on the assembling side. This arrangement of the relevant conductor tracks, which is as congruent as possible, allows parasitic inductances to be reduced.

According to at least one embodiment, electrical through-holes for the electrical contact surfaces for the further capacitor are located in the edge region of the substrate as viewed from above on the assembling side. The same preferably applies to the associated electrical connection surfaces on the mounting side. That is, in contrast to the electrical through-holes for the supply voltage for the semiconductor laser diode, the electrical connections for the further capacitor are arranged at the edge of the substrate.

According to at least one embodiment, the carrier layers on the one hand and the insulating layers on the other hand are arranged in blocks. That is, none of the insulating layers is located between the carrier layers and none of the carrier layers is located between the insulating layers.

According to at least one embodiment, two or three or four or five of the insulating layers are present. Preferably, exactly two or exactly three insulating layers are present, in particular three insulating layers.

According to at least one embodiment, at least three or five of the carrier layers are present. Alternatively or additionally, the number of carrier layers is at most 20 or 12 or eight.

For example, a total of at least four or at least five or at least seven substrate layers are present. Alternatively or additionally, the total number of substrate layers is at most 25 or 18 or 12, with preferably more carrier layers than insulating layers.

According to at least one embodiment, the substrate serves to reduce a size of conductor loops. That is, due to the small thickness of the insulating layers, relative to the carrier layers, a size of conductor loops, defined by the conductor tracks and the associated electrical through-holes, and thus a size of inductances is reduced compared to a substrate with substrate layers of a uniform thickness. This applies in particular to the electrical interconnection of the further capacitor and alternatively or additionally to the electrical interconnection of the semiconductor laser diode itself.

In addition, a semiconductor laser is provided. The semiconductor laser includes a substrate as disclosed in connection with one or more of the above embodiments. Features of the semiconductor laser are therefore also disclosed for the substrate, and vice versa.

In at least one embodiment, the semiconductor laser comprises a substrate. Furthermore, the semiconductor laser comprises a semiconductor laser diode that is electrically connected to the associated contact surfaces, for example, indirectly, such as via bonding wires, or directly, such as via soldering. Further, the semiconductor laser comprises a laser capacitor at and/or on the associated contact surfaces. Furthermore, a control chip, in particular an IC, is provided at and/or on the associated contact surfaces.

According to at least one embodiment, the semiconductor laser is surface mountable. In particular, the semiconductor laser is electrically mountable only via the mounting side and is also mechanically and thermally mountable at the same time.

According to at least one embodiment, the semiconductor laser further comprises the further capacitor. The further capacitor is mounted on the associated contact surfaces on the assembling side.

According to at least one embodiment, the further capacitor, which is set up in particular as a buffer capacitor for a switching element of the control chip to the semiconductor laser diode, is located directly next to the control chip when viewed from above. It is possible that the further capacitor is also located directly next to electrical contact surfaces associated with the semiconductor laser diode. In this way, geometric distances between the further capacitor and the control chip and between the further capacitor and the semiconductor laser diode can be minimized when viewed from above.

According to at least one embodiment, the contact surfaces of the semiconductor laser diode are located next to a connection area of the semiconductor laser diode when viewed from above on the assembling side. This means that the semiconductor laser diode is preferably attached, in particular soldered, over the entire surface of the connection area for efficient thermal contacting, whereby the connection area does not need to have any further electrical function.

The semiconductor laser diode is then preferably electrically contacted both on the anode side and on the cathode side via bonding wires which lead to the respectively assigned contact surfaces. As an alternative to a semiconductor laser diode which is contacted both on the anode side and on the cathode side via electrically conductive bonding wires, the semiconductor laser diode can be soldered on the anode side or on the cathode side, in particular over the entire respective surface, and/or the semiconductor laser diode is mounted without bonding wires by means of several electrical contact surfaces which face the assembling side.

According to at least one embodiment, the semiconductor laser further comprises a cover. The cover is attached, for example, glued, to the substrate. The cover is preferably made of an electrically insulating material such as a plastic or a ceramic.

According to at least one embodiment, a laser radiation is emitted by the semiconductor laser diode in operation in a direction away from the substrate through the cover, in particular through a window of the cover. In this case, the laser radiation can be emitted directly by the semiconductor laser diode in this direction or there is a deflection optics between the semiconductor laser diode and the cover, relative to a beam path of the laser radiation.

In particular, the semiconductor laser diode is a single-channel or a multi-channel surface emitting laser diode with a vertical cavity, Vertical Cavity Surface Emitting Laser or VCSEL for short.

According to at least one embodiment, a distance between the semiconductor laser diode and the laser capacitor and/or a distance between the semiconductor laser diode and the control chip is at most 0.2 mm, in particular at most 150 μm or 100 μm. Such small distances allow the lengths of current paths to be reduced.

According to at least one embodiment, the semiconductor laser is set up for high currents to energize the semiconductor laser diode. In this case, the semiconductor laser diode is preferably operated in pulsed mode. In particular, the semiconductor laser is set up for intermittent current strengths through the semiconductor laser diode of at least 2 A or 3 A and/or of at most 15 A or 10 A.

According to at least one embodiment, the semiconductor laser and in particular the substrate is set up for small rise times of a current and thus a laser emission of the semiconductor laser diode. For example, the rise time is at most 2 ns or 1 ns or 0.5 ns. For example, the rise time is a 10-90 time, that is, a time within which the current rises from 10% to 90% of a maximum current intensity.

The semiconductor laser described here is set up, for example, for distance measurements by means of Time of Flight, ToF for short. A wavelength of the laser radiation emitted by the semiconductor laser in operation is preferably in the near-infrared spectral range, in particular at at least 850 nm and/or at at most 1.6 μm.

### BRIEF DESCRIPTION OF THE DRAWINGS

In the following, a substrate described herein and a semiconductor laser described herein are explained in more detail with reference to the drawing by means of exemplary embodiments. Identical reference signs indicate identical elements in the individual figures. The relationships of the elements are not shown to scale, however, but rather individual elements may be shown exaggeratedly large for better understanding.

In the Figures:

FIGS. 1 and 2 show schematic perspective views of an embodiment of a semiconductor laser described herein with a substrate described herein,

FIGS. 3, 6 and 10 show schematic circuit diagrams of the semiconductor laser of FIG. 2,

FIGS. 4, 7 and 11 show schematic side views of the semiconductor laser of FIG. 2, and

FIGS. 5, 8 and 9 show schematic perspective views with a substrate drawn transparent of the semiconductor laser of FIG. 2 with focus on different electrical aspects.

### DETAILED DESCRIPTION

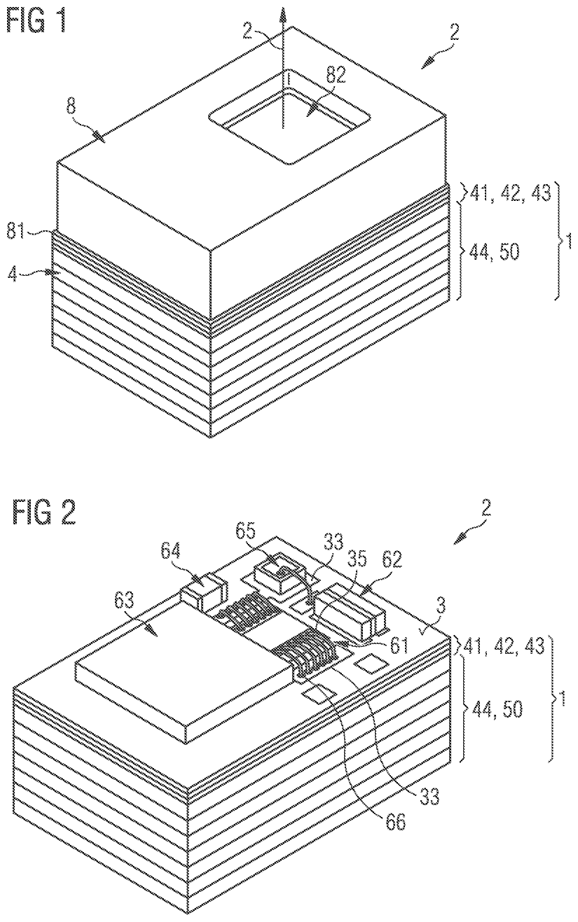

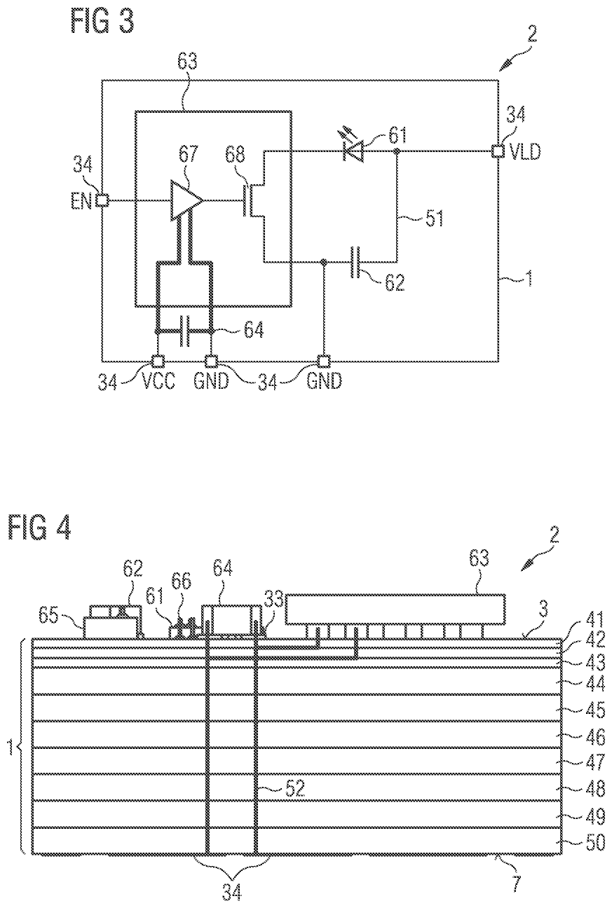

FIGS. 1 to 11 illustrate an embodiment of a semiconductor laser 2 in various representations. FIGS. 1 and 2 refer to the semiconductor laser 2 as a whole, and FIGS. 3 to 11 highlight various electrical aspects that are individually or preferably cumulatively realized in semiconductor lasers described herein.

In the three-dimensional representation of the semiconductor laser 2 according to FIG. 1, it can be seen that the semiconductor laser 2 has a substrate 1. The substrate 1 comprises a plurality of substrate layers 4. The substrate layers 4 are divided into insulating layers 41, 42, 43 on the one hand and carrier layers 44 . . . 50 on the other hand. The insulating layers 41, 42, 43 are designed to be as thin as possible, and the carrier layers 44 . . . 50 serve to mechanically stabilize the substrate 1 and thus the semiconductor laser 2.

Furthermore, the semiconductor laser 2 comprises a cover 8. The cover 8 is, for example, made of a plastic. Optionally, the cover 8 is attached to the substrate 1 with an adhesive 81. The cover 8 preferably comprises a window 82, for example, made of a glass, of plastic or also of a material that is transparent to a laser radiation L, such as sapphire. In operation of the semiconductor laser 2, the laser radiation L is preferably emitted in the direction away from the substrate 1 through the window 82.

In the following figures, the cover 8 is not drawn in each case to simplify the illustration.

In FIG. 2, it can be seen that an assembling side 3 is defined on a topmost substrate layer, which is formed by a first insulating layer 41. Electrical contact surfaces 33 and at least one connection area 35 are located on the assembling side 3. It is possible that the connection area 35, in contrast to the contact surfaces 33, has no further electrical function.

A control chip 63 and a further capacitor 64 are attached to the contact surfaces 33 on the assembling side 3. A semiconductor laser diode 61 is located on the connection area 35, next to which a laser capacitor 62 is mounted on assigned contact surfaces 33. Optionally, the semiconductor laser 2 further comprises a photodiode 65, for example, for diagnostic purposes and/or for driving the semiconductor laser diode 61.

The semiconductor laser diode 61 and optionally the photodiode 65 are electrically contacted, for example, via bonding wires 66. The other components 62, 63, 64 are preferably electrically contacted without bonding wires so that these components 62, 63, 64 can be surface mounted.

Deviating from the exemplary representation of the semiconductor laser 2, other numbers of insulating layers and carrier layers may also be present. For example, there can be only two insulating layers and at least three carrier layers.

For example, a height of the substrate 1 in the direction perpendicular to the assembling side 3 is at least 1 mm or 2 mm and/or at most 5 mm or 3 mm, for example approximately 2.3 mm. For example, a width of the substrate 1 is at least 1.5 mm or 2.5 mm and/or at most 8 mm or 5 mm, for example about 3.5 mm. A length of the substrate 1 is, for example, at least 2 mm or 3.5 mm and/or at most 10 mm or 8 mm, for example about 5.4 mm. A thickness of the insulating layers 41, 42, 43 is, for example, about 100 μm, whereas the carrier layers 44 . . . 50 have, for example, a thickness of about 350 μm. The aforementioned values may apply individually or cumulatively to all embodiments of the substrate 1 and the semiconductor laser 2.

FIG. 3 schematically illustrates the electrical interconnection of components 61, 62, 63, 64. These components are connected to each other via electrical conductor tracks 51 and via electrical through-holes 52, which are not explicitly shown in FIG. 3.

On a mounting side 7 opposite to the assembling side 3, see also FIG. 4, there are several electrical connection surfaces 34 for external electrical contacting of the semiconductor laser 2 and thus of the substrate 1. In the example of FIG. 4, the connection surfaces 34 are located on the tenth substrate layer 4, which, according to the applied counting, is equal to the tenth carrier layer 50.

Electrical connection areas 34 are provided for a supply voltage VLD for the semiconductor laser diode 61, for a supply voltage VCC for the additional capacitor 64, for ground connections GND and for a trigger connection EN.

Optionally, further connection areas 34, not explicitly drawn, can be provided, for example for diagnostic purposes for reading out the optional photodiode 65, not drawn in FIG. 3.

The control chip 63 preferably comprises a driver 67 for a switching element 68. The driver 67 is, for example, an operational amplifier. The switching element 68 is preferably a transistor, in particular a MOSFET.

In FIGS. 3 and 4, particular attention is paid to a current path when the semiconductor laser diode 61 is turned on and thus when the switching element 68 is activated. Here, the further capacitor 64, which serves as a buffer capacitor, is used. The relevant current paths are highlighted.

A trigger signal at the terminal EN turns on the semiconductor laser 2. Thereby, the driver 67 draws significant current to charge a gate of the switching element 67 within a few 10 ps. Series resistances and inductances between a voltage supply of the driver 67 and a current source can cause a significant voltage drop of a few 100 mV at the connection surfaces 34 for the associated supply voltage VCC of the further capacitor 64. This can cause problems with the electromagnetic compatibility of the semiconductor laser 2.

In FIGS. 4 and 5, the associated circuitry of the further capacitor 64 within the substrate 1 is highlighted. That is, in the schematic side view of FIG. 4 and the three-dimensional view of FIG. 5, the current routing is illustrated as highlighted in the circuit diagram of FIG. 3.

The associated electrical conductor tracks 51a, 51b run between the first insulating layer 41 and the second insulating layer 42 and between the second insulating layer 42 and the third insulating layer 43, respectively. Viewed from above on the assembling side 3, these conductor tracks 51a, 51b run as congruently as possible in order to ensure low parasitic inductances.

The electrical through-holes 52 for the further capacitor 64 are located in an edge region of the substrate 1, seen in plan view on the assembling side. The same preferably also applies to the further capacitor 64 itself.

The associated through-holes 52, also referred to as vias, preferably run partially or completely adjacent to the control chip 63, in particular below the further capacitor 64. Further through-holes 52 are provided to create an interconnection between the conductor tracks 51a, 51b in the various planes and the through-holes 52 from the connection surface 34 and towards the further capacitor 64 and the control chip 63.

Thus, a conduction of a supply voltage of the control chip 63 is realized essentially between the insulating layers 41, 42, 43, with a direct overlap between the conductor tracks 51a, 51b for VCC and GND in order to achieve the lowest possible inductances.

The substrate 1 thus preferably has a power part for the semiconductor laser diode 61 with thin ceramic layers in the form of the insulating layers 41, 42, 43. The remaining substrate 1 represents a signal part with thicker ceramic layers in the form of the carrier layers 44 . . . 50.

A typical operating current for the pulsed semiconductor laser 2 is in the range of 3.5 A to 4 A, for example, with a rise time in the range around 0.5 ns. A capacitance of the laser capacitor 62 is in the range around 1 μF, for example. A thickness of the electrical conductor tracks between the substrate layers 4 is, for example, at least 10 μm or 15 μm and/or at most 50 μm or 30 μm. A diameter of the through-holes 52 is, for example, at least 50 μm and/or at most 0.2 mm, for example about 100 μm. A distance between adjacent conductor tracks and/or through-holes in the substrate 1 is preferably at least 50 μm or 0.1 mm to avoid electrical short circuits. The above values may apply individually or cumulatively to all embodiments of the semiconductor laser 2 and the substrate 1.

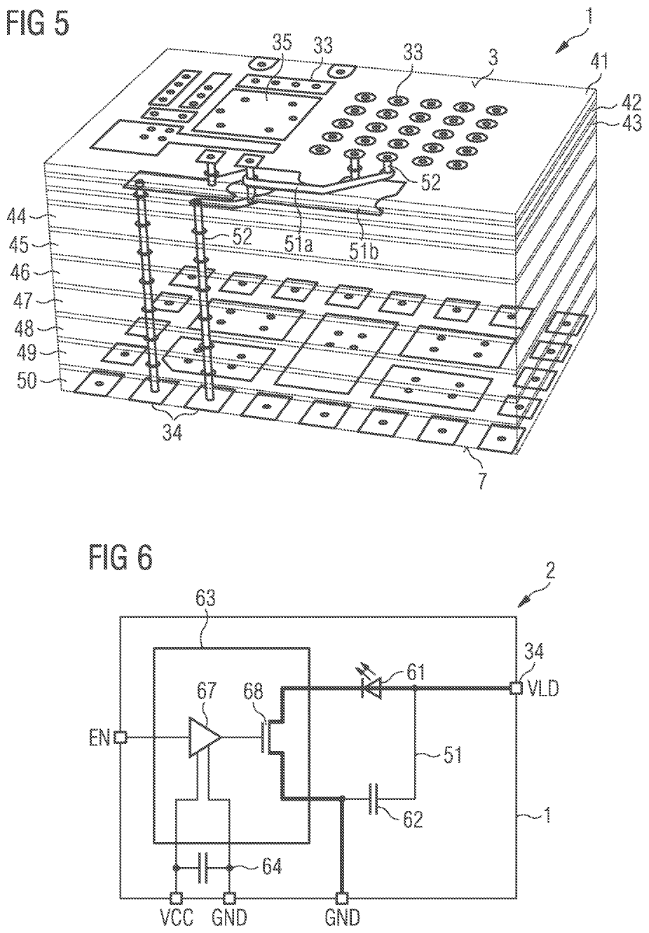

FIGS. 6 through 9 illustrate another aspect of the semiconductor laser 2 described herein. When the semiconductor laser 2 is turned on, current pulses of several amperes flow from the supply voltage VLD through the laser, through the control chip 3 and back to the ground connection GND, see the current path highlighted in FIG. 6.

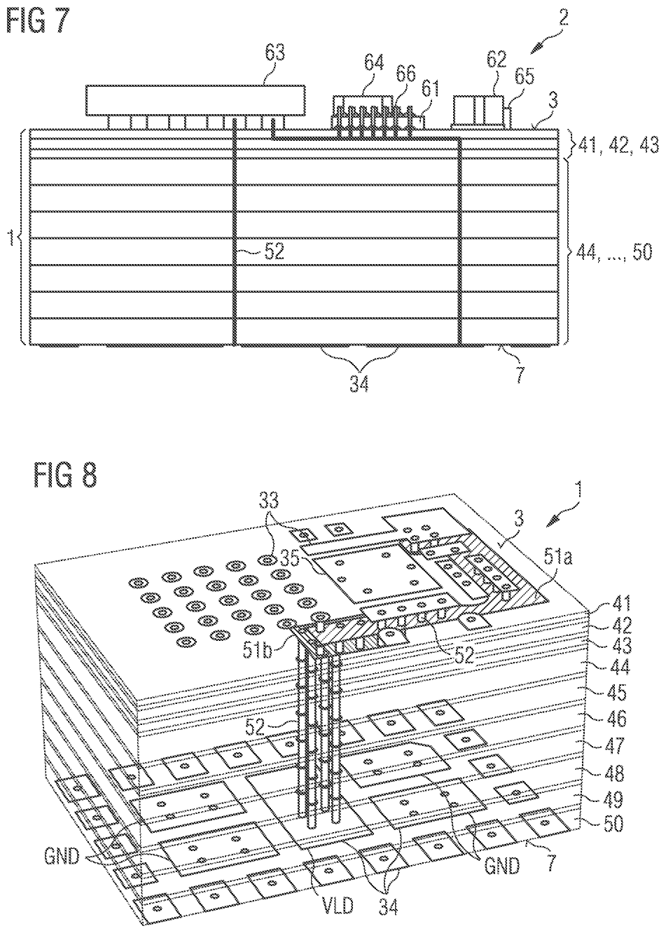

An area between these components on the assembling side 3 of the substrate 1 towards the connection surfaces 34 on the mounting side 7 can act as an antenna and emit radio radiation, see FIG. 7. This in turn can cause problems with the electromagnetic compatibility of the semiconductor laser 2.

In particular, it can be seen from FIG. 8 that the through-holes 52 for the supply voltage VLD are arranged in a central region of the substrate 1 as seen in a top view of the assembling side 3. In other words, these through-holes 52 preferably run centrally through the substrate 1. These through-holes 52 extend at least as far as the second insulating layer 42 and may also be partially guided as far as the contact surfaces 33 for the control chip 63.

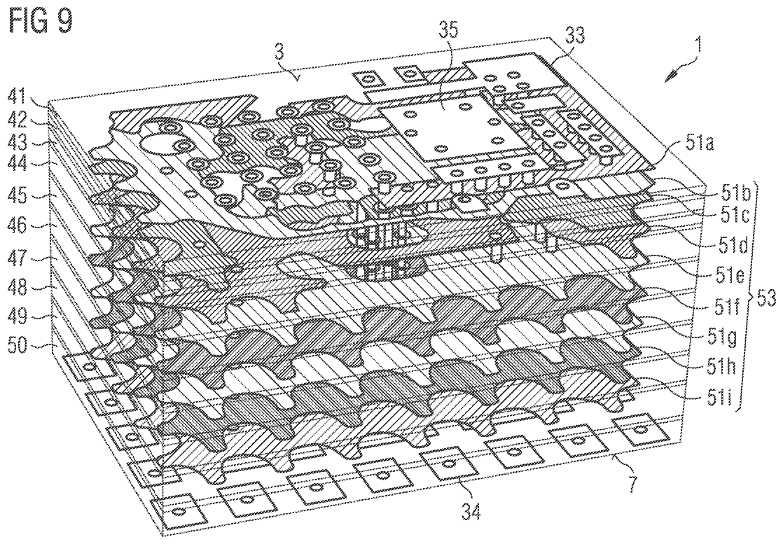

In particular in FIG. 9 it can be seen that electrical conductor tracks 51b, . . . 51e between the substrate layers 4 further away from the assembling side 3 are designed as shielding conductor tracks 53, which are connected to GND and, viewed from above the assembling side 3, run all the way around the through-holes 52 for VLD. This ensures efficient shielding of the through-holes 52 for VLD. This results in significantly reduced radio frequency radiation.

There may be several connection surfaces 34 for GND, for example, on two sides of exactly one connection surface 34 for VLD. The connection surfaces 34 for VLD and GND can be surrounded by smaller connection surfaces 34 for VCC, EN, further GND and for control signals or diagnostic data that are not explicitly drawn, see FIG. 8.

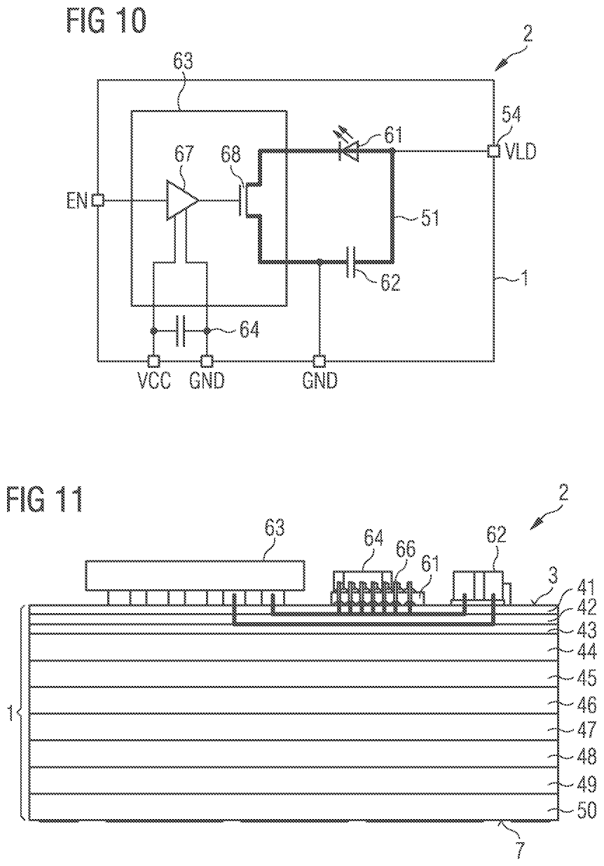

FIGS. 10 and 11 show another aspect of the substrate 1 described herein. When the semiconductor laser diode 61 is turned on, a series resistance and inductance between the power supply and the semiconductor laser diode 61 limit a rise time of the current to typically a few 10 ns. Therefore, the laser capacitor 62 is used to provide the necessary current to build up the laser emission in the sub-nanosecond range.

With the substrate 1 described here, an inductance caused by a conductor loop is minimized in the highlighted current path. This is achieved in particular by guiding this current path on both sides of the second insulating layer 42, so that only the thickness of the second insulating layer 42, seen in cross-section, contributes to the size of the conductor loop. The small thickness of the insulating layers 41, 42, 43 can thus reduce the rise time of the laser emission.

Briefly summarized, the substrate 1 of the semiconductor laser 2 described herein can be used to particularly address the following three aspects:
Low inductances can be achieved in driving the switching element 67 in the region of the further capacitor 64, since the associated electrical conductor tracks can be close together and approximately congruent, see FIGS. 3 to 5.
Radio frequency radiation can be reduced by having through-holes for the supply voltage VLD running centrally through the substrate 1 and laterally shielded via the shielding conductor tracks 53, see FIGS. 6 to 9.
A small rise time of a laser emission can be achieved by having current paths between the laser capacitor 62 and the semiconductor laser diode 61 having low inductances when viewed in cross section, see FIGS. 10 and 11.

The components shown in the figures preferably follow one another in the sequence indicated, in particular directly one after the other, unless otherwise described. Components not touching each other in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise described.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1. A substrate configured for a semiconductor laser diode having a plurality of substrate layers, wherein
the substrate layers comprise a plurality of insulating layers,
the substrate layers comprise a plurality of carrier layers which are thicker than the insulating layers,
a plurality of electrical contact surfaces for the semiconductor laser diode, for a laser capacitor and for a control chip are located on an assembling side of a first, uppermost insulating layer, and the substrate layers are numbered consecutively starting with the first insulating layer in the direction away from the assembling side, and
electrical conductor tracks, which electrically interconnect the electrical contact surfaces for the semiconductor laser diode, the laser capacitor and the control chip, are located on the one hand between the first insulating layer and a second insulating layer and on the other hand between the second insulating layer and a third substrate layer.

2. The substrate according to claim 1,
wherein all substrate layers are of the same material, which is a ceramic,
wherein a thickness of the insulating layers is each between 40 μm and 0.2 mm inclusive, and
wherein a thickness of the carrier layers is each between 0.2 mm and 0.8 mm inclusive and the carrier layers are thicker than the insulating layers by at least a factor of 2 and are configured for mechanical stabilization of the substrate.

3. The substrate according to claim 1, wherein at least one electrical connection surface, which is configured for a supply voltage for the semiconductor laser diode, leads from an outer mounting side of a last one of the carrier layers to at least the second insulating layer, the mounting side is a side of the substrate opposite the assembling side,
wherein at least one electrical through-hole for this connection surface being arranged in a central region of the substrate, as seen in plan view of the assembling side.

4. The substrate according to claim 3, wherein the at least one electrical through-hole for the connection surface for the supply voltage for the semiconductor laser diode between the carrier layers is surrounded in each case by at least one shielding conductor track, and the shielding conductor tracks located between the carrier tracks are connected to at least one electrical connection surface on the mounting side for a ground connection.

5. The substrate according to claim 4, wherein there is a plurality of the electrical through-holes for the connection surface for the supply voltage for the semiconductor laser diode, wherein these electrical through-holes run directly and uninterruptedly from precisely one associated connection surface at the mounting side to at least the second insulating layer and, as seen in plan view of the assembling side, are located beyond an electrical connection area for the control chip.

6. The substrate according to claim 1, comprising electrical contact surfaces on the assembling side for a further capacitor, wherein electrical conductor tracks, which electrically interconnect the electrical contact surfaces for the further capacitor and the electrical contact surfaces for the control chip, are located on the one hand between the first insulating layer and the second insulating layer and on the other hand between the second insulating layer and the third substrate layer.

7. The substrate according to claim 6, wherein the electrical conductor tracks, which electrically interconnect the contact surfaces for the further capacitor and for the control chip, run at least partially one above the other as seen in plan view of the assembling side.

8. The substrate according to claim 1,
wherein electrical through-holes at the assembly side for electrical contact surfaces for a further capacitor are arranged in an edge region of the substrate, as seen in plan view of the assembling side.

9. The substrate according to claim 1, wherein the carrier layers on the one hand and the insulating layers on the other hand are arranged in blocks, so that none of the carrier layers is located between the insulating layers and vice versa.

10. The substrate according to claim 1, comprising between two and five, inclusive, of said insulating layers and between three and 20, inclusive, of said carrier layers,
wherein there are more of the support layers than of the insulating layers.

11. The substrate according to claim 1, wherein due to a smaller thickness of the insulating layers compared with a larger thickness of the carrier layers, a size of conductor loops defined by the electrical conductor tracks, and thus a size of inductances, is reduced compared to a substrate having substrate layers with only one uniform thickness.

12. A semiconductor laser comprising
a substrate according to claim 1,
a semiconductor laser diode electrically connected to the associated electrical contact surfaces,
a laser capacitor on associated contact surfaces, and
a control chip on associated contact surfaces,
wherein the semiconductor laser is surface mountable.

13. The semiconductor laser according claim 12, further comprising a further capacitor mounted on associated contact surfaces, wherein the further capacitor is located directly adjacent to the control chip as seen in plan view on the assembling side.

14. The semiconductor laser according to claim 12,
wherein the electrical contact surfaces of the semiconductor laser diode are located next to an electrical connection area of the semiconductor laser diode as seen in plan view on the assembling side, and
wherein the semiconductor laser diode is electrically connected to the associated contact surfaces in each case by means of a plurality of bonding wires.

15. The semiconductor laser according to claim 12,
further comprising a cover bonded to the substrate,
wherein a laser radiation is emitted from the semiconductor laser diode in operation in a direction away from the substrate through the cover, and the semiconductor laser diode is a surface emitting laser diode having a vertical cavity.

16. The semiconductor laser according to claim 12,
wherein a distance between the semiconductor laser diode and the laser capacitor and a distance between the semiconductor laser diode and the drive chip are each at most 0.2 mm.

17. The semiconductor laser according to claim 12,
which is configured for a temporary current for the semiconductor laser diode of at least 2 A and for a rise time of a current for the semiconductor laser diode of 1 ns or less.

18. A substrate configured for a semiconductor laser diode having a plurality of substrate layers, wherein
the substrate layers comprise a plurality of insulating layers,
the substrate layers comprise a plurality of carrier layers which are thicker than the insulating layers,
a plurality of electrical contact surfaces for the semiconductor laser diode, for a laser capacitor and for a control chip are located on an assembling side of a first, uppermost insulating layer, and the substrate layers are numbered consecutively starting with the first insulating layer in the direction away from the assembling side, and
electrical conductor tracks, which electrically interconnect the electrical contact surfaces for the semiconductor laser diode, the laser capacitor and the control chip, are located on the one hand between the first insulating layer and a second insulating layer and on the other hand between the second insulating layer and a third substrate layer,
at least one electrical connection surface, which is configured for a supply voltage for the semiconductor laser diode, leads from an outer mounting side of a last one of the carrier layers to at least the second insulating layer,
at least one electrical through-hole for this connection surface being arranged in a central region of the substrate, as seen in plan view of the assembling side,
the at least one electrical through-hole for the connection surface for the supply voltage for the semiconductor laser diode between the carrier layers is surrounded in each case by at least one shielding conductor track, and the shielding conductor tracks located between the carrier layers are connected to at least one electrical connection surface on the mounting side for a ground connection,
there are at least three electrical through-holes for the connection surface for the supply voltage for the semiconductor laser diode, and
these at least three electrical through-holes run directly and uninterruptedly from precisely one associated connection surface at the mounting side to at least the second insulating layer and, as seen in plan view of the assembling side, are located below an electrical connection area for the control chip.
